(19) United States
(12) Patent Application Publication
(10) Pub. No.: US 2012/0236644 A1
(43) Pub. Date: Sep. 20, 2012

(54) SEMICONDUCTOR STORAGE DEVICE

(75) Inventor: Takuya FUTATSUYAMA, Yokohama-shi (JP)

(73) Assignee: Kabushiki Kaisha Toshiba, Tokyo (JP)

(21) Appl. No.: 13/418,955

(22) Filed: Mar. 13, 2012

(30) Foreign Application Priority Data
Mar. 18, 2011 (JP) 2011-060596

(51) Int. Cl. G11C 16/04

(52) U.S. Cl. 365/185.11

(57) ABSTRACT

A semiconductor storage device according to an embodiment includes: a memory cell array including plural word lines, plural bit lines, and plural memory cells each of which is selected by the word line and the bit line, the memory cell array being divided into plural blocks, some of the word lines being set to a specific word line, at least some of or all the memory cells in each block being set to specific memory cells, the memory cell being accessed by the specific word line, the specific data except user data being stored in the specific memory cell; and an erasing circuit that erases the memory cell of the memory cell array, the erasing circuit referring to the specific data stored in the specific memory cell belonging to the certain block during an erasing operation of the memory cell belonging to the certain block.

### CROSS-REFERENCE TO RELATED APPLICATIONS

This application is based upon and claims the benefit of priority from the prior Japanese Patent Application No. 2011-60596, filed on Mar. 18, 2011, the entire contents of which are incorporated herein by reference.

### FIELD

Embodiments described herein relate generally to a semiconductor storage device.

### BACKGROUND

Conventionally, in the semiconductor storage device, a large capacity is implemented by a microfabrication of a memory cell. In this regard, among the semiconductor storage devices, the microfabrication of a NAND flash memory is easily performed, because many memory cells are connected in series to reduce a ratio of a contact occupied per memory cell.

However, with the progress of the microfabrication of the memory cell, unfortunately a data breakage is easily generated by an increase of an influence of intercell interference, and degradation in reliability becomes prominent by the increased number of erasing times.

### BRIEF DESCRIPTION OF THE DRAWINGS

FIG. 1 is a block diagram of a semiconductor storage device according to a first embodiment;

FIG. 2 is a circuit diagram of a memory cell array of the semiconductor storage device;

FIG. 3 is a view illustrating function allocation of a word line of the semiconductor storage device;

FIG. 4 is a view illustrating the function allocation of the word line of the semiconductor storage device;

FIG. 5 is a view illustrating an operating sequence during an erasing cycle of the semiconductor storage device;

FIG. 6 is a view illustrating operating waveforms during the erasing cycle of the semiconductor storage device;

FIG. 7 is a view illustrating the operating waveforms during the erasing cycle of the semiconductor storage device;

FIG. 8 is a view illustrating the operating waveforms during the erasing cycle of the semiconductor storage device;

FIG. 9 is a view illustrating the operating waveforms during the erasing cycle of the semiconductor storage device;

FIG. 10 is a view illustrating the operating waveforms during the erasing cycle of the semiconductor storage device;

FIG. 11 is a view illustrating the operating waveforms during the erasing cycle of the semiconductor storage device;

FIG. 12 is a view illustrating the operating waveforms during the erasing cycle of the semiconductor storage device;

FIG. 13 is a view illustrating the operating waveforms during the erasing cycle of the semiconductor storage device;

FIG. 14 is a view illustrating the operating waveforms during the erasing cycle of the semiconductor storage device;

FIG. 15 is a view illustrating the operating waveforms during the erasing cycle of the semiconductor storage device;

FIG. 16 is a view illustrating the operating waveforms during the erasing cycle of the semiconductor storage device;

FIG. 17 is a view illustrating an operating sequence during a write cycle of the semiconductor storage device;

FIG. 18 is a view illustrating specific data writing and reading methods of a semiconductor storage device according to a second embodiment;

FIG. 19 is a view illustrating specific data writing and reading methods of a semiconductor storage device according to a third embodiment;

FIG. 20 is a view illustrating specific data writing and reading methods of a semiconductor storage device according to a fourth embodiment;

FIG. 21 is a view illustrating a spacer patterning process;

FIG. 22 is a view illustrating the spacer patterning process;

FIG. 23 is a view illustrating the spacer patterning process;

FIG. 24 is a view illustrating the spacer patterning process;

FIG. 25 is a view illustrating the spacer patterning process;

FIG. 26 is a view illustrating the spacer patterning process;

FIG. 27 is a view illustrating the spacer patterning process;

FIG. 28 is a view illustrating the spacer patterning process;

FIG. 29 is a view illustrating the spacer patterning process;

FIG. 30 is a view illustrating the spacer patterning process;

FIG. 31 is a view illustrating the spacer patterning process;

FIG. 32 is a view illustrating the spacer patterning process;

FIG. 33 is a view illustrating the spacer patterning process;

FIG. 34 is a view illustrating the spacer patterning process;

FIG. 35 is a view illustrating the spacer patterning process;

FIG. 36 is a view illustrating the spacer patterning process;

FIG. 37 is a view illustrating the spacer patterning process; and

FIG. 38 is a view illustrating the spacer patterning process.

### DETAILED DESCRIPTION

A semiconductor storage device according to an embodiment includes: a memory cell array including plural word lines, plural bit lines, and plural memory cells each of which is selected by the word line and the bit line, the memory cell array being divided into plural blocks, some of the word lines being set to a specific word line, at least some of or all the memory cells in each block being set to specific memory cells, the memory cell being accessed by the specific word line, the specific data except user data being stored in the specific memory cell; and an erasing circuit that erases the memory cell of the memory cell array, the erasing circuit referring to the specific data stored in the specific memory cell belonging to the certain block during an erasing operation of the memory cell belonging to the certain block.

Hereinafter, semiconductor storage devices according to embodiments of the invention will be described with reference to the drawings.

### First Embodiment

<Configuration of Semiconductor Storage Device>

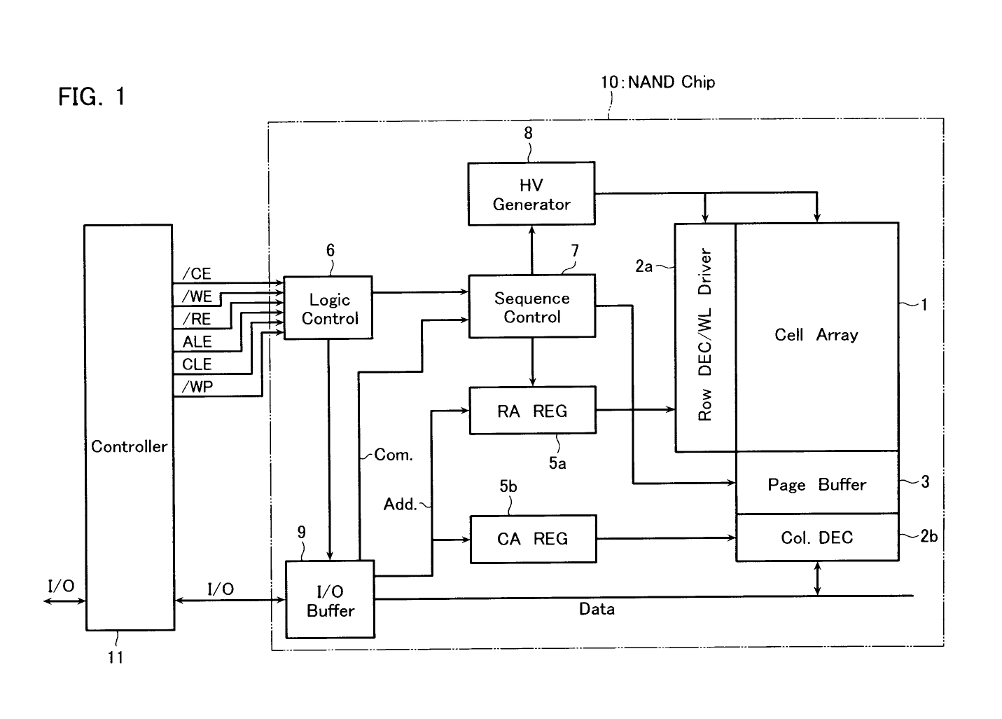

FIG. 1 is a block diagram illustrating a configuration of a NAND flash memory that is of a semiconductor storage device according to a first embodiment. The NAND flash memory includes a NAND chip 10 and a controller 11 that controls the NAND chip 10.

A memory cell array 1 constituting the NAND chip 10 is configured to array plural floating gate type memory cells MC in a matrix as described below. An erasing circuit that erases data includes a row decoder/word line driver 2a, a column decoder 2b, a page buffer 3, and a high-voltage generator 8. The row decoder/word line driver 2a drives a word line and a selected gate line of the memory cell array 1. The page buffer 3 includes a sense amplifier for one page and a data retaining circuit for one page, and writes and reads data in and from the memory cell array 1 in units of pages.

In the read data for one page of the page buffer 3, columns are sequentially selected by the column decoder 2b and output to an external I/O terminal through an I/O buffer 9. Write data supplied from the I/O terminal is selected by the column decoder 2b and loaded on the page buffer 3. The write data for one page is loaded on the page buffer 3. Row address and column address signals are input through the I/O buffer 9 and transferred to the row decoder 2a and the column decoder 2b, respectively. A row address register 5a retains an erasing block address in an erasing operation, and retains a page address in a write operation and a read operation. A leading column address for loading the write data before a start of the write operation and a leading column address for the read operation are input to a column address register 5b. The column address register 5b retains the input column address until a write enable signal /WE or a read enable signal /RE is toggled on a predetermined condition.

A logic control circuit 6 controls input of a command or an address and input/output of data based on control signals such as a chip enable signal /CE, a command enable signal CLE, an address latch enable signal ALE, the write enable signal /WE, and the read enable signal /RE. The read operation and the write operation are performed by the commands. In response to the command, the sequence control circuit 7 performs the read operation and sequence control of the write or erasing. The high-voltage generator 8 is controlled by the sequence control circuit 7 to generate predetermined voltages necessary for various operations.

The controller 11 controls the write and read of the data on the condition suitable for a current write state of the NAND chip 10. Part of read control (described later) may be performed on the side of the NAND chip 10.

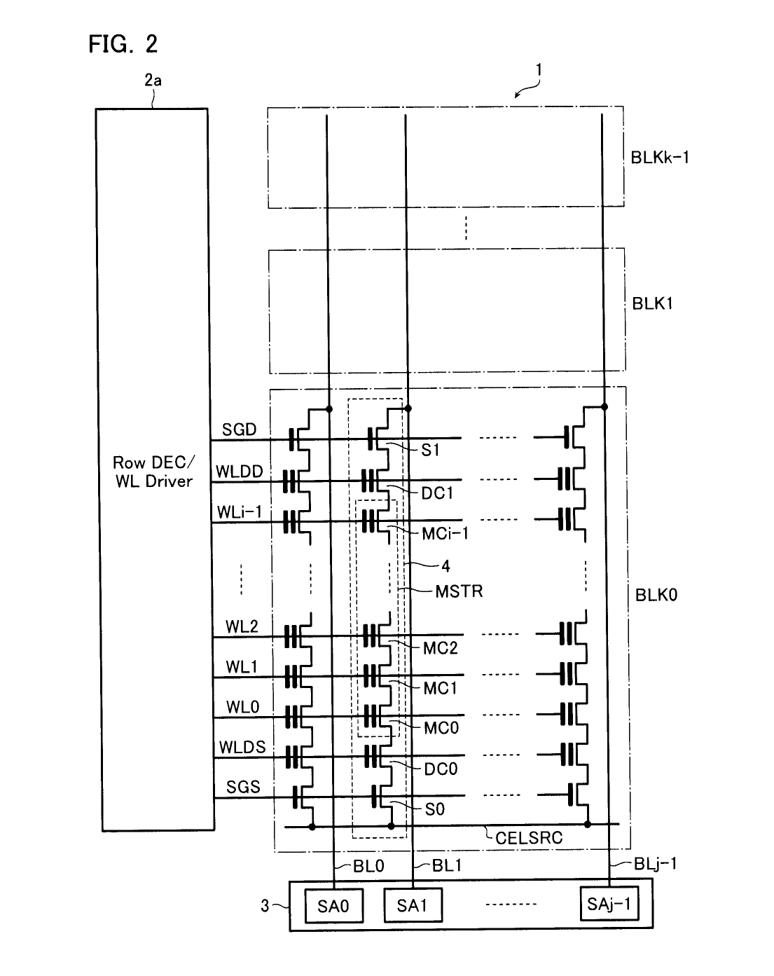

FIG. 2 illustrates a configuration of the cell array 1. Referring to FIG. 2, a NAND cell unit 4 is constructed by a memory string MSTR including n series-connected memory cells MC0 to MC1-i and selection gate transistors S0 and S1 connected to both ends of the memory string MSTR. A source of the selection gate transistor S0 is connected to a common source line CELSRC, and a drain of the selection gate transistor S1 is connected to a bit line BL (BL0 to BLj-1). A control gate of each of the memory cells MC0 to MC1-1 is connected to a word line WL (WL0 to WLi-1), and gates of the selection gate transistors S0 and S1 are connected to selection gate lines SGS and SGD.

As illustrated in FIG. 2, dummy word lines WLDS and WLDD having structures equal to that of the word line WL and dummy cells DC0 and DC1 having structures equal to that of the memory cell MC may be provided between the memory string MSTR and the selection transistors S0 and S1 as needed basis. In this case, because a gate induction drain leak current influenced by the selection gate transistors S0 and S1 is relaxed, disturb resistance can be improved in the memory cells MC0 and MCn-1 located at both ends of the memory string MSTR.

A range of plural memory cells MC along one word line WL constitutes a page that becomes a unit of collective data read and data write. A range of plural NAND cell units 4 arrayed in a direction of the word line WL constitutes a cell block BLK that becomes a unit of collective data erasing. In FIG. 2, plural cell blocks BLK0 to BLKk-1 that share the bit line BL are arrayed in a direction of the bit line BL to construct the cell array 1.

The word line WL and the selection gate lines SGS and SGD are driven by the row decoder 2a. Each bit line BL is connected to a sense amplifier SA (SA0 to SAj-1) of the page buffer 3.

The microfabrication of the memory cells MC0 to MC1-1 having the above configurations may be performed in the case that the high-density, large-capacity semiconductor device is implemented. For example, in the case that a spacer patterning process that is one of microfabrication technologies is used, the memory cells MC0 to MC1-i can be formed by a line and space pattern (hereinafter referred to as an “L/pattern”) having a fine pitch exceeding resolution of a lithography technology.

However, with the progress of the microfabrication of the memory cell, unfortunately the data breakage is easily generated by the increase of the influence of the intercell interference and the degradation in reliability becomes prominent by the increased number of erasing times. A degree of the change associated with the microfabrication also varies depending on a position of the block in the memory cell array.

Because a central portion of the memory cell array tends to differ from an end portion in a write speed of the memory cell, it is necessary to change a writing method depending on a block position.

In this regard, in the semiconductor storage device, for example, a circuit operating parameter common to the whole device is prepared in a ROM fuse region of the memory cell array, and the circuit operation is properly implemented in the whole device using the circuit operating parameter. However, it is difficult to absorb a variation of a characteristic depending on the block position with only the circuit operating parameter.

Therefore, in the first embodiment, specific data depending on the block is prepared as an example of data except user data in addition to the circuit operating parameter common to the whole device. The specific data is data that optimally operates the circuit in each block to be accessed. For example, the specific data adjusts the circuit operating parameter according to the block to be accessed.

The specific data is stored in a predetermined memory cell constituting a block as described below, and the specific data is used while updated according to the access to the block. For example, in the case that the number of write/erasing times is stored as the specific data, the optimum write/erasing operation can be performed according to the number of write/erasing times in each block.

Therefore, by controlling the circuit operation according to the block or the number of write/erasing times, the degradation caused by the increased number of write/erasing times can be suppressed, or the variation of the characteristic in each block can be absorbed.

<Disposition of Memory Cell in which Specific Data is Stored>

A disposition of the memory cell in which the specific data is stored in the semiconductor storage device of the first embodiment will be described below.

Hereinafter, sometimes the memory cell in which the specific data is stored is referred to as a “specific memory cell”, the memory cell in which only the user data is stored is referred to as a “general memory cell”, and the memory cell in which the user data is not stored is referred to as a “dummy cell”. Accordingly, in the case that many bits can be stored in the specific memory cell, the specific data and the user data can be stored in the specific memory cell while mixed with each other.

Sometimes the word line to which at least one specific memory cell is connected is referred to as a “specific word line”, the word line to which only the dummy cell is connected is referred to as a “dummy word line”, and other word lines are referred to as “general word lines”. Accordingly, in the case that only the specific data is stored in the memory cell selected by the word line, the word line can double as the specific word line and the dummy word line.

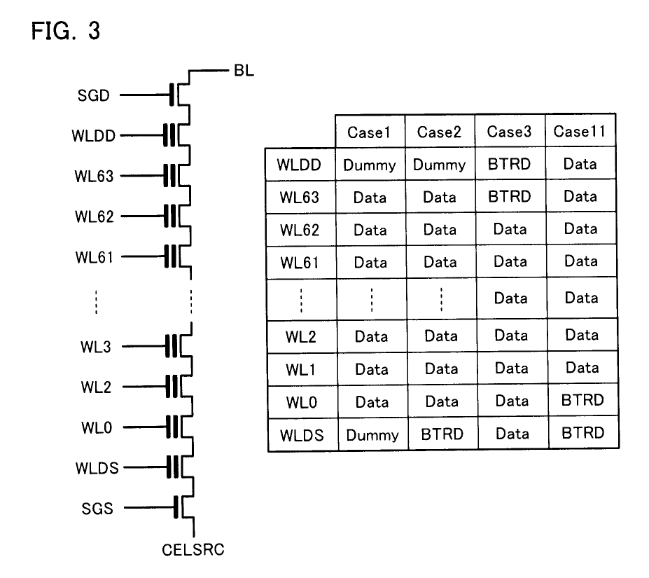

FIG. 3 is a view illustrating function allocation of the word line in the case of i=64 in FIG. 2. In FIG. 3, the specific word line is expressed by “BTRD (Block Trimming ROM fuse Data)”, the general word line is expressed by “Data”, and the dummy word line is expressed by “Dummy”.

A case 1 is a comparative example of the first embodiment. In the case 1, the word lines WLDS and WLDD are directly used as the dummy word lines, and the specific word line is not provided.

A case 2 is an example in which the word line WLDS, which is used as the dummy word line in the case 1, is used as the specific word line.

A case 3 is an example in which the word lines WL63 and WLDD on a drain-gate side are used as the specific word lines. In the case 3, the word lines WLDS and WL0 to WL62 are used as the general word lines to ensure the 64 general word lines similarly to the case 1.

A case 11 is an example in which the word lines WLDS and WL0 on a source-gate side are used as the specific word lines. In the case 11, the word lines WL1 to WL63 and WLDD are used as the general word lines to ensure the 64 general word lines similarly to the case 1.

In the above cases, the case 3 and the case 11 can deal with more pieces of specific data compared with the case 2.

For example, sometimes four interconnections each of which has a line width of ¼ F are formed through the two spacer patterning process from a line pattern having a minimum processing size F by the resolution of the lithography technology. In this case, desirably the number of word lines is set to a multiple of 4 from the viewpoint of process construction.

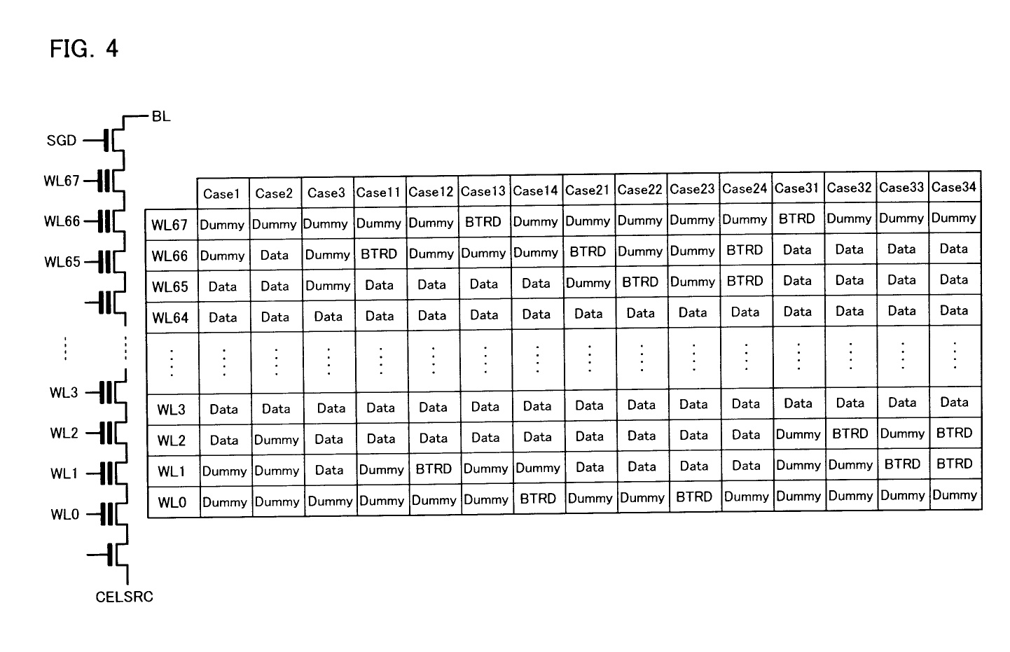

The function allocation of the 68 word lines that is of the multiple of 4 will be described with reference to FIG. 4.

The case 1 to the case 3 are the comparative examples of the first embodiment, and the examples in which the specific word line is not provided.

In the case 1, the word lines WL2 to WL65 are used as the general word lines, and the word lines WL0, WL1, WL66, and WL67 are used as the dummy word lines. In the case 2, the word lines WL3 to WL66 are used as the general word lines, and the word lines WL0 to WL3 and WL67 are used as the dummy word lines. In the case 3, the word lines WL1 and WL65 to WL67 are used as the specific word lines, and the word lines WL0 and WL65 to WL67 are used as the dummy word lines. In each of the case 1 to the case 3, in the 68 word lines, the 64 word lines are used as the general word lines, and the four word lines are used as the dummy word lines.

In the first embodiment, the function is allocated to the word lines of the case 1 to the case 3 as follows.

Each of the case 11 to a case 14 is an example in which one dummy word line in the four dummy word lines of the case 1 is used as the specific word line. In each of the case 11, the case 12, the case 13, and the case 14, the word lines WL66, WL1, WL67, and WL0 are used as the specific word lines.

Each of a case 21 to a case 23 is an example in which one dummy word line in the four dummy word lines of the case 3 is used as the specific word line. In each of the case 21, the case 22, and the case 23, the word lines WL66, WL65, and WL0 are used as the specific word lines.

In the case 24, the word lines WL66 and WL67 in the four dummy word lines of the case 3 are used as the specific word lines.

Each of a case 31 to a case 33 is an example in which one dummy word line in the four dummy word lines of the case 2 is used as the specific word line. In each of the case 31, the case 32, and the case 33, the word lines WL67, WL2, and WL1 are used as the specific word lines.

In the case 34, the word lines WL2 and WL1 in the four dummy word lines of the case 3 are used as the specific word lines.

In the above cases, the case 24 and the case 34 can deal with more pieces of configuration data compared with other cases. In the case 13, the case 14, the case 21 and the case 23, because the dummy word line is provided between the specific word line and the general word line, the disturb of the specific data which is generated by the access to the user data can be suppressed. Among others, in the case 21 and the case 33, because the word lines on both sides of the specific word line constitute the dummy word lines, it is said that the function allocation of the word lines can more successfully suppress the disturb of the specific data.

The allocation of the specific word line is not limited to the cases illustrated in FIGS. 3 and 4.

<Sequence during Erasing Cycle>

An operating sequence during an erasing cycle of the semiconductor storage device of the first embodiment will be described below.

As used herein, the erasing cycle means a cycle including the erasing operation in which data erasing is performed to a specific block and a preparation of the peripheral circuit and post-processing for the erasing operation. The erasing cycle is typically regarded to be a cycle during which an erasing busy signal is active. However, the erasing cycle is not necessarily matched with the cycle during which the erasing busy signal is active.

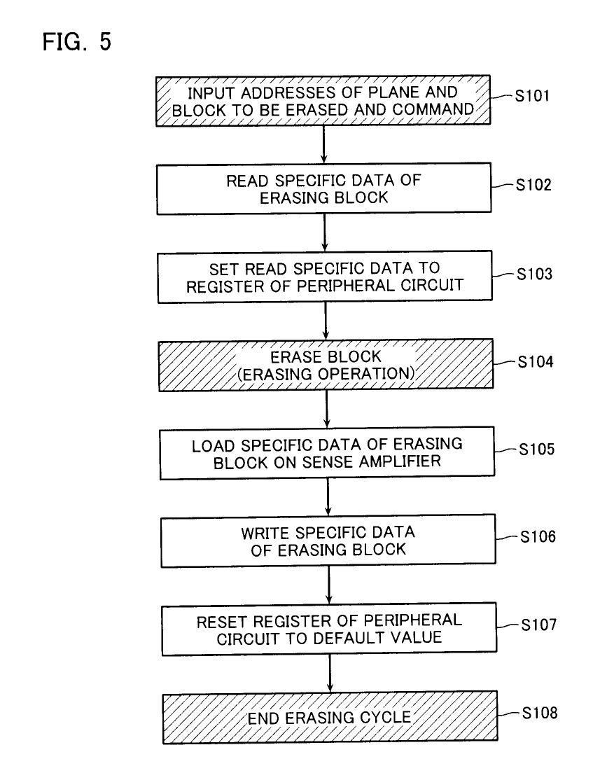

FIG. 5 is a view illustrating an operating sequence during the erasing cycle. Steps S101, S104, and S108 indicated by hatched lines in FIG. 5 correspond to the operating sequence during the erasing cycle of the related art. However, operations in Steps S101, S104, and S108 are not necessarily matched with those of the related art.

In Step S101, addresses to be erased of a plane and a block and a command are input from the outside through the controller 11. The addresses of the plane and the block are transmitted to the row address register 5a and the column address register 5b through the I/O buffer 9. The command is transmitted to the sequence control circuit 7 through the logic control circuit 6.

In Step S102, the specific data, which is stored in the specific memory cell of the block (hereinafter referred to as an “erasing block”) that becomes an erasing target, is read on the page buffer 3.

In Step S103, the specific data retained in the page buffer 3 is set to a register of a peripheral circuit such as the sequence control circuit 7.

In Step S104, the circuit operating parameter is adjusted using the specific data set to the register of the peripheral circuit, and the peripheral circuit is operated according to the adjusted circuit operating parameter to erase the data of the erasing block (erasing operation).

In Step S105, the new specific data is generated based on pieces of information such as a processing time of the erasing operation and a voltage applied to the memory cell in Step S104, and the new specific data is loaded on the sense amplifier SA of the page buffer 3.

In Step S106, the specific data loaded on the sense amplifier SA of the page buffer 3 is written in the specific memory cell of the erasing block.

Finally, in Step S107, the specific data retained in the register of the peripheral circuit is reset to a predetermined default value. Then the erasing cycle is ended (Step S108).

As described above, in the first embodiment, the circuit operating parameter is adjusted using the specific data prepared in each block, so that the optimum erasing operation can be implemented in each block.

The operation during the erasing cycle of the semiconductor storage device of the first embodiment is not limited to the operating sequence of FIG. 5. For example, the write of the specific data in Step S106 may be performed any time after Step S103.

In the case of the operating sequence during the erasing cycle of the first embodiment of FIG. 5, a specific data read step and a specific data write step are added to the case of the related art. However, the newly-added steps can be processed in an extremely short time compared with the erasing operation performed in units of blocks, the erasing cycle is not lengthened to much compared with the that of the related art.

An operating waveform in each step of the operating sequence of FIG. 5 will be described below. It is assumed that the following operating waveforms are the case 11 of FIG. 4, and it is assumed that the specific data is stored in the specific memory cell of one bit/cell, which is connected to the word line WL66. Because the operating waveform in each step depends on an operating method, the description is made while some typical operating methods are assumed.

Step S103 of FIG. 5 is processed in the background of Step S104 or processed between Steps S102 and S104, and Step S103 is an operation that does not emerge on a node of the memory cell. Similarly, Step S105 of FIG. 5 is processed in the background of Step S104 or processed between Steps S104 and S106, and Step S105 is the operation that does not emerge on the node of the memory cell. Accordingly, the descriptions of the operating waveforms in Steps S103 and S105 are not included.

First, Step S102 will be described.

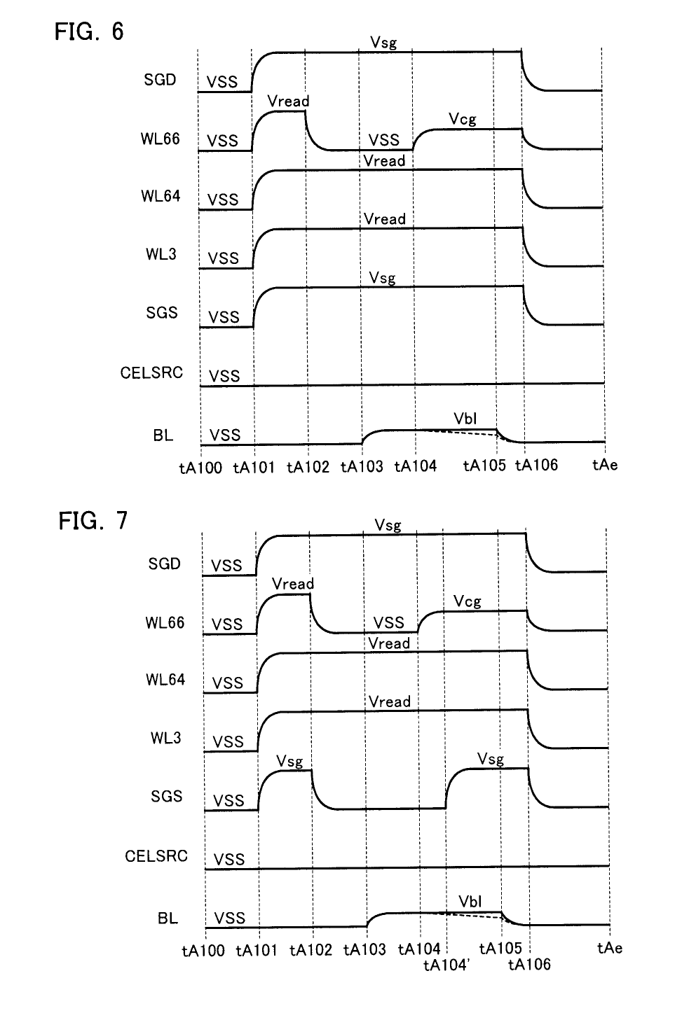

FIG. 6 illustrates operating waveforms in Step S102 for use of an ABL (All Bit Line) method in which an even-numbered bit line and an odd-numbered bit line are simultaneously accessed.

A cycle of times tA100 to tA101 is an initial state at a starting point of Step S102.

In a cycle of times tA101 to tA102, the selection gate lines SGS and SGD are boosted to a voltage Vsg (for example, 3.5 V). The word lines WL2 to WL66 are boosted to a voltage Vread (that is of a second voltage, for example, 6 V). As a result, the bit line BL and the common source line CELSRC are electrically connected to initialize a channel potential at the memory cell MC. However, the cycle of the times tA101 to tA102 is occasionally omitted.

Then, in a cycle of times tA102 to tA103, the specific word line WL66 is discharged to, for example, a voltage VSS (0 V).

Then, in a cycle of times tA103 to tA104, the bit line BL is charged to a voltage Vb1 (for example, 0.5 V).

Then, in a cycle of times tA104 to tA105, a voltage Vcg (that is of a first voltage, for example, 0.5 V) necessary to read the specific data is applied to the specific word line WL66. As a result, the voltage at the bit line BL changes according to the specific data stored in the specific memory cell MC66. The sense amplifier SA of the page buffer 3 detects the change in voltage to determine the specific data.

Then, in a cycle of times tA105 to tA106, the bit line BL is discharged to, for example, the voltage VSS (0 V).

Finally, in a cycle of times tA106 to tAe, the voltages at the selection gate lines SGD and SGS and the word lines WL3 to WL66 are discharged.

Step S102 is described above for the use of the ABL method. In the first embodiment, it is noted that the voltage at the specific word line WL66 is lower than the voltages at the general word lines WL2 to WL65 in the cycle of times tA104 to tA105.

In FIG. 6, sometimes the common source line CELSRC is charged to the voltage higher than the voltage VSS (0 V). Sometimes a well CPWELL in which the memory cell MC is formed is charged to the voltage higher than the voltage VSS (0 V). In this case, the voltages at the bit line BL, the selection gate lines SGS and SGD, and the word lines WL2 to WL66 are substantially increased according to the voltage at the well CPWELL.

FIG. 7 illustrates the operating waveforms in Step S102 for use of a bit line shield method in which the even-numbered bit line and the odd-numbered bit line are alternately accessed while the bit line that is not accessed is used as a shield line.

Because the cycle of the times tA100 to tA102 is identical to that of FIG. 6, the description is not repeated here.

Then, in the cycle of the times tA102 to tA103, the selection gate line SGS and the specific word line WL66 are discharged to, for example, the voltage VSS (0 V).

Then, in the cycle of the times tA103 to tA104, the bit line BL is charged to the voltage Vb1 (for example, 0.5 V).

Then, in a cycle of times tA104 to tA104′, the predetermined voltage Vcg (for example, 0.5 V) necessary to read the specific data is applied to the specific word line WL66.

Then, in a cycle of times tA104′ to tA105, the selection gate line SGS is charged to the voltage Vsg (for example, 0.5 V). As a result, the voltage at the bit line BL changes according to the specific data stored in the specific memory cell MC66. The sense amplifier SA of the page buffer 3 detects the change in voltage to determine the specific data.

Because the cycle of the times tA105 to tAe is identical to that of FIG. 6, the description is not repeated here.

Step S102 is described above for the use of the bit line shield method. In the first embodiment, it is noted that the voltage at the specific word line WL66 is lower than the voltages at the general word lines WL2 to WL65 in the cycle of times tA104′ to tA105.

In FIG. 7, sometimes the common source line CELSRC is charged to the voltage higher than the voltage VSS (0 V). Sometimes the well CPWELL in which the memory cell MC is formed is charged to the voltage higher than the voltage VSS (0 V). In this case, the voltages at the bit line BL, the selection gate lines SGD and SGS, and the word lines WL2 to WL66 are substantially increased according to the voltage at the well CPWELL.

Step S104 will be described below.

Step S104 is performed by steps of an erasing verify read step BV→a write step BP→an erasing step BE→the erasing verify read step BV→a write step BP2→an erasing verify read step BV2→ . . . (hereinafter, a repetition of the erasing step BE→the erasing verify read step BV→the write step BP2→the erasing verify read step BV2).

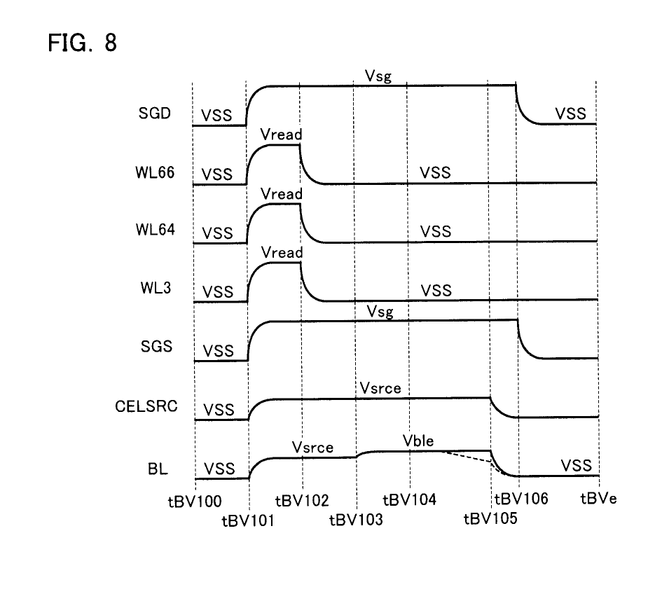

FIG. 8 illustrates the operating waveforms in the erasing verify read step BV of Step S104 for the use of the ABL method.

The cycle of times tBV100 to tBV101 is the initial state at the starting point of the erasing verify read step BV.

In a cycle of times tBV101 to tBV102, the selection gate lines SGD and SGS are boosted to the voltage Vsg (for example, 3.5 V). The word lines WL2 to WL66 are boosted to the voltage Vread (for example, 6 V). As a result, the bit line BL and the common source line CELSRC are electrically connected to initialize a channel potential at the memory cell MC. However, the cycle of the times tBV101 to tBV102 is occasionally omitted. At the same time, the voltage at the bit line BL, the common source line CELSRC, and the well CPWELL in which the memory cell MC is formed are charged to a voltage Vsrce (for example, 1 V).

Then, in a cycle of times tBV102 to tBV103, the word lines WL2 to WL66 are discharged to, for example, the voltage VSS (0 V).

Then, in a cycle of times tBV103 to tBV105, the bit line BL is charged to a voltage Vble (=Vsrce+Vb1=1.5 V). Then the voltage at the bit line BL changes. The voltage change is detected by the sense amplifier SA of the page buffer 3, and the erasing operation is completed when a discharge from the bit line BL is detected.

Then, in a cycle of times tBV105 to tBV106, the bit line BL, the common source line CELSRC, and the well CPWELL are discharged to, for example, the voltage VSS (0 V).

Finally, in a cycle of times tBV106 to tBVe, the selection gate lines SGS and SGD are discharged to, for example, the voltage VSS (0 V).

The erasing verify read step BV in Step S104 is described above for the use of the ABL method. In the first embodiment, it is noted that the voltages at the word lines WL64 and WL66 are lower than the voltages at the selection gate lines SGS and SGD in the cycle of times tBV103 to tBV105.

Whether a threshold of the memory cell MC is substantially higher than −1 V can be detected by the erasing verify read step BV in Step S104.

Depending on an operating method, sometimes the erasing verify read step BV in Step S104 for the use of the ABL method is individually performed with respect to the even-numbered word line WLe and the odd-numbered word line WLo.

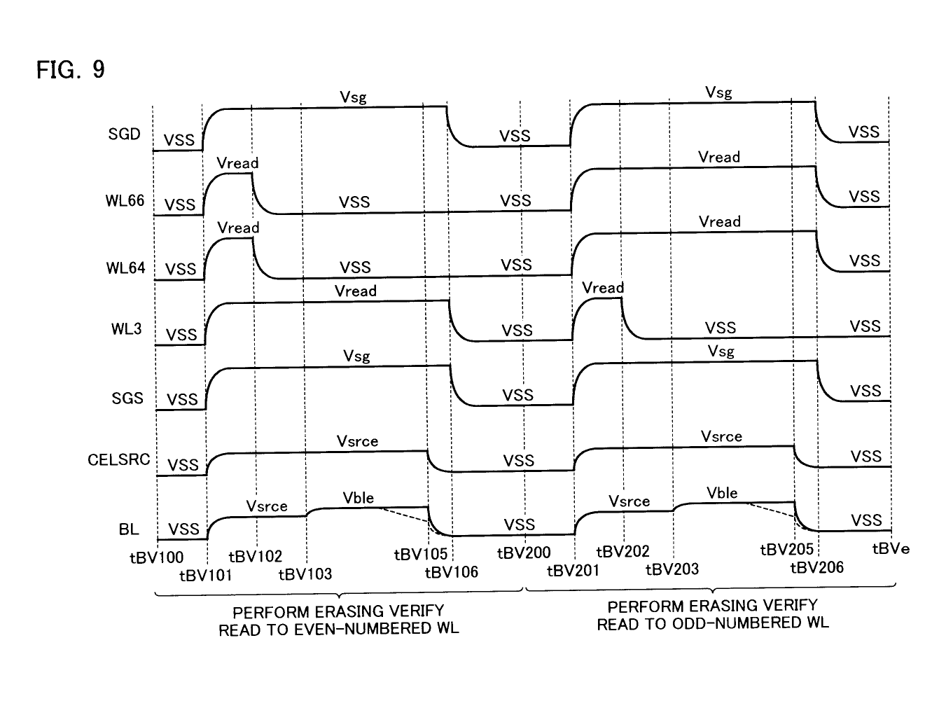

Specifically, as illustrated in FIG. 9, the erasing verify is performed to the even-numbered word line WLe in the cycle of the times tBV100 to tBV200, and the erasing verify is performed to the odd-numbered word line WLo in the cycle of the times tBV200 to tBVe.

At this point, the cycle of the times tBV100 to tBV200 of FIG. 9 is equal to the cycle of the times tBV100 to tBVe of FIG. 8 except the operating waveform of the odd-numbered word line WLo. In FIG. 9, the odd-numbered word line WLo is maintained at the voltage Vread (for example, 6 V) in the cycle of the times tBV102 to tBV106, and discharged to, for example, the voltage VSS (0 V) in the cycle of the times tBV106 to tBV200.

The cycle of the times tBV200 to tBVe of FIG. 9 is equal to the cycle of the times tBV100 to tBVe of FIG. 8 except the operating waveform of the even-numbered word line WLe. In FIG. 9, the even-numbered word line WLe is maintained at the voltage Vread (for example, 6 V) in the cycle of the times tBV202 to tBV206, and discharged to, for example, the voltage VSS (0 V) in the cycle of the times tBV206 to tBVe.

The use of the ABL method is described above, and becomes the erasing verify read step BV in Step S104 for the use of the ABL method in the case that the erasing verify read step BV is individually performed to the even-numbered word line WLe and the odd-numbered word line WLo.

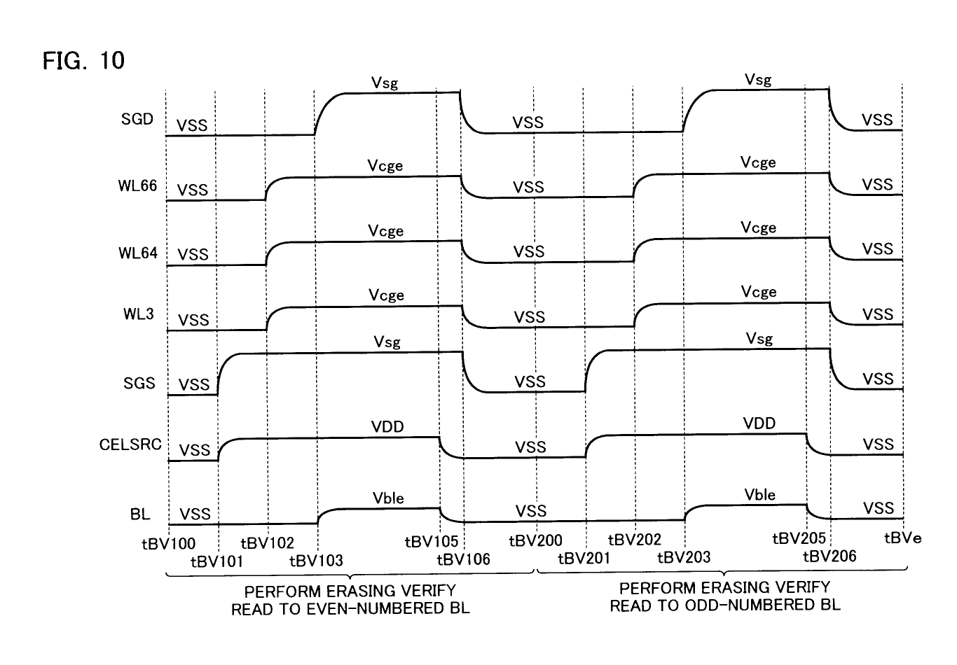

FIG. 10 illustrates the operating waveforms in the erasing verify read step BV of Step S104 for the use of the bit line shield method.

The cycle of times tBV100 to tBV101 is the initial state at the starting point of the erasing verify read step BV.

In a cycle of times tBV101 to tBV102, the selection gate line SGS is boosted to the voltage Vsg (for example, 3.5 V). The common source line CELSRC is charged to a voltage VDD (for example, 2.5 V).

Then, in the cycle of the times tBV102 to tBV103, the word lines WL2 to WL66 are boosted to a voltage Vcge (for example, 0.5 V).

Then, in the cycle of the times tBV103 to tBV105, the selection gate line SGD is boosted to the voltage Vsg (for example, 3.5 V). As a result, the voltage at the even-numbered bit line BLe changes. When the voltage Vb1 at the bit line BLe is increased, the erasing operation of the memory cell MCe is completed to the bit line BLe.

Then, in the cycle of the times tBV105 to tBV106, the bit line BL and the common source line CELSRC are discharged to, for example, the voltage VSS (0 V).

Then, in the cycle of the times tBV106 to tBV200, the selection gate lines SGS and SGD and the word lines WL2 to WL66 are discharged to, for example, the voltage VSS (0 V).

In the cycle of the times tBV200 to tBVe, the same operation as the cycle of the times tBV100 to tBV200 is performed to the odd-numbered bit line BLo.

The erasing verify read step BV in Step S104 is described above for the use of the bit line shield method.

In the first embodiment, in the cycles of times tBV103 to tBV105 and the times tBV203 to tBV205, it is noted that the voltages at the word lines WL64 and WL66 are lower than the voltages at the selection gate lines SGS and SGD and that the voltage at the well CPWELL is 0 V.

Depending on a cell current of the memory cell MC, whether the threshold of the memory cell MC is substantially higher than about −0.5 V to about −1.5 V can be detected by the erasing verify read step BV in Step S104.

Depending on the operating method, sometimes the erasing verify read step BV in Step S104 for the use of the bit line shield method is individually performed with respect to the even-numbered word line WLe and the odd-numbered word line WLo.

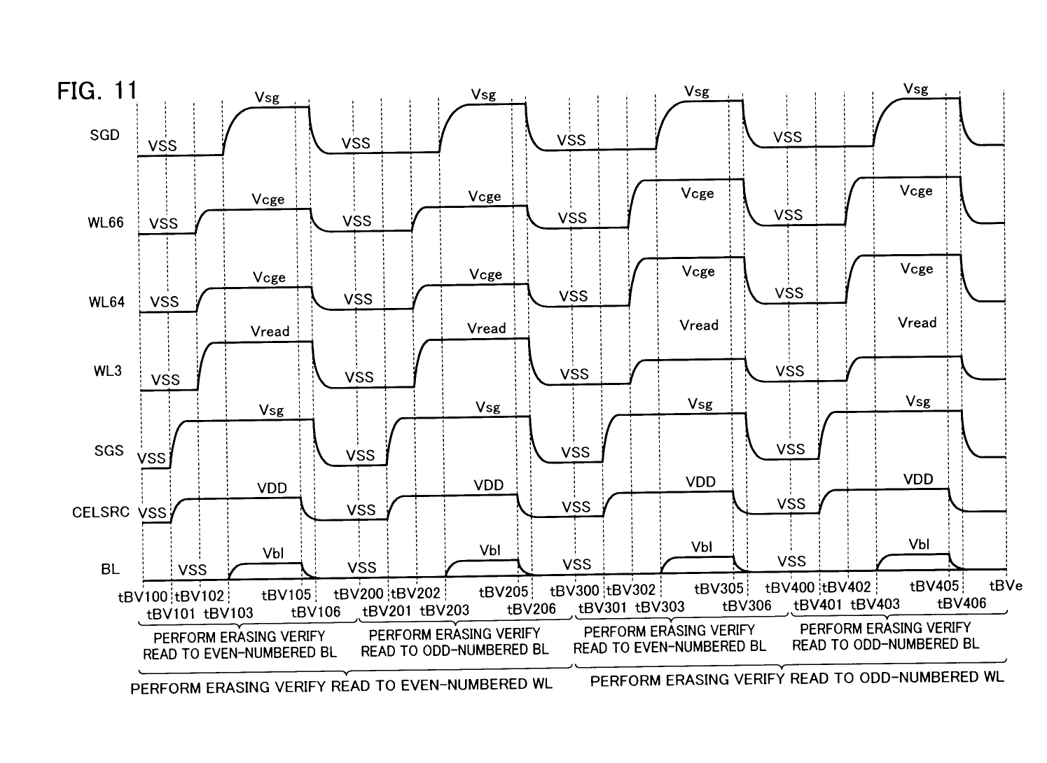

Specifically, as illustrated in FIG. 11, the erasing verify read is performed to the even-numbered word line WLe in a cycle of times tBV100 to tBV300, and the erasing verify read is performed to the odd-numbered word line WLo in a cycle of times tBV300 to tBVe.

At this point, the cycle of the times tBV100 to tBV300 of FIG. 11 is equal to the cycle of the times tBV100 to tBVe of FIG. 10 except the operating waveform of the odd-numbered word line WLo. In FIG. 11, the word line WLo is boosted to the voltage Vread (for example, 6 V) in the cycles of the times tBV102 to tBV105 and the times tBV202 to tBV205.

The cycle of the times tBV300 to tBVe of FIG. 11 is equal to the cycle of the times tBV100 to tBVe of FIG. 10 except the operating waveform of the even-numbered word line WLe.

In FIG. 11, the word line WLe is boosted to the voltage Vread (for example, 6 V) in the cycles of the times tBV302 to tBV305 and the times tBV402 to tBV405.

The use of the bit line shield method is described above, and becomes the erasing verify read step BV in Step S104 for the use of the bit line shield method in the case that the erasing verify read step BV is individually performed to the even-numbered word line WLe and the odd-numbered word line WLo.

The erasing verify read step BV2 in Step S104 is identical to the erasing verify read step BV in Step S104 except that the voltage Vsrce or Vcge is higher than that of FIGS. 8 to 11.

In the write step BP2 of Step S104, a manipulation to slightly write back the erased memory cell MC is performed in order to prevent excessive erasing of the erased memory cell MC. Therefore, in the erasing verify read step BV2, the erasing verify read is performed with a threshold voltage that is equal to or slightly higher than the determination threshold voltage (Vsrce or Vcge) of the erasing verify read. In the case that the number of memory cells MC exceeding the determination threshold voltage exceeds a predetermined number, the write (write back) verify read in the write step BP2 is completed.

The write step BP2 will be described as the assumption to the write step BP in Step S104.

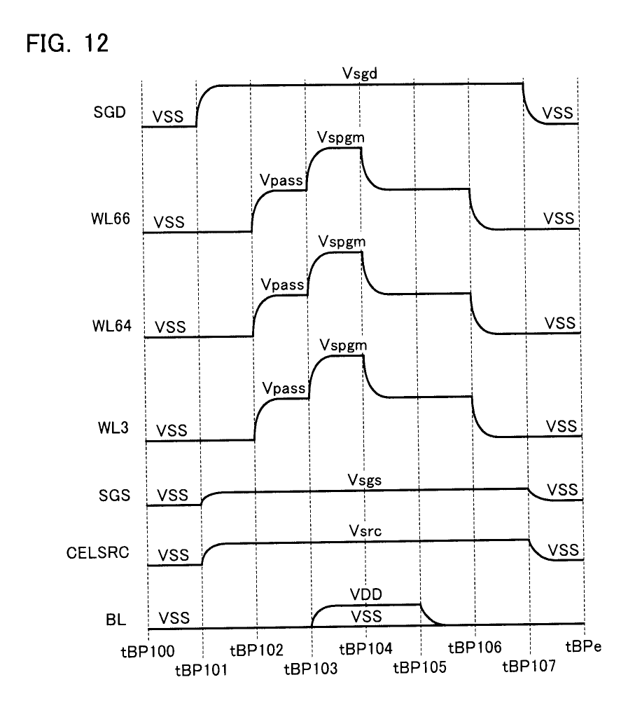

FIG. 12 illustrates the operating waveforms in the write step BP2 of Step S104 when the simultaneous write is performed to all the word lines in the block.

A cycle of times tBP100 to tBP101 is an initial state at a starting point of the write step BP2.

Then, in a cycle of times tBP101 to tBP102, the common source line CELSRC and the selection gate lines SGS and SGD are charged to a voltage Vsrc (for example, 2 V), a Vsgs (for example, 1.5 V), and a Vsgd (for example, 2.5 V), respectively.

Then, in a cycle of times tBP102 to tBP103, the word lines WL2 to WL66 are charged to a voltage Vpass (for example, 8 V).

Then, in a cycle of times tBP103 to tBP104, the word lines WL2 to WL66 are charged to a voltage Vspgm (for example, about 13 V) necessary to write the data. The bit line BL through which the write is not performed is charged to the power supply voltage VDD (for example, 2.5 V), and the bit line BL through which the write is performed is charged to, for example, the voltage VSS (0 V).

Then, in a cycle of times tBP104 to tBP105, the word lines WL2 to WL66 are discharged to the voltage Vpass (for example, 8 V).

Then, in a cycle of times tBP105 to tBP106, the bit line BL is discharged to, for example, the voltage VSS (0 V).

Then, in a cycle of times tBP106 to tBP107, the word lines WL2 to WL66 are discharged to, for example, the voltage VSS (0 V).

Finally, in a cycle of times tBP107 to tBPe, the common source line CELSRC and the selection gate lines SGD and SGS are discharged to, for example, the voltage VSS (0 V).

The write step BP2 of Step S104 is described above when the simultaneous write is performed to all the word lines in the block. In the first embodiment, it is noted that all the word lines WL2 to WL66 become the highest voltage (for example, about 13 V) in the cycle of the times tBP103 to tBP104.

In FIG. 12, sometimes another charge or discharge is added in the cycle of the times tBP100 to tBP101. The well CPWELL has the voltage of 0 V.

The write step BP in Step S104 is performed before the erasing step BE. In the write step BP, the write is performed to the memory cell MC in the erased state to enhance the threshold of the memory cell MC as high as the threshold of the memory cell MC in the write state.

The write step BP2 is identical to the write step BP in Step S104 except a high voltage Vspgm (for example, 20V).

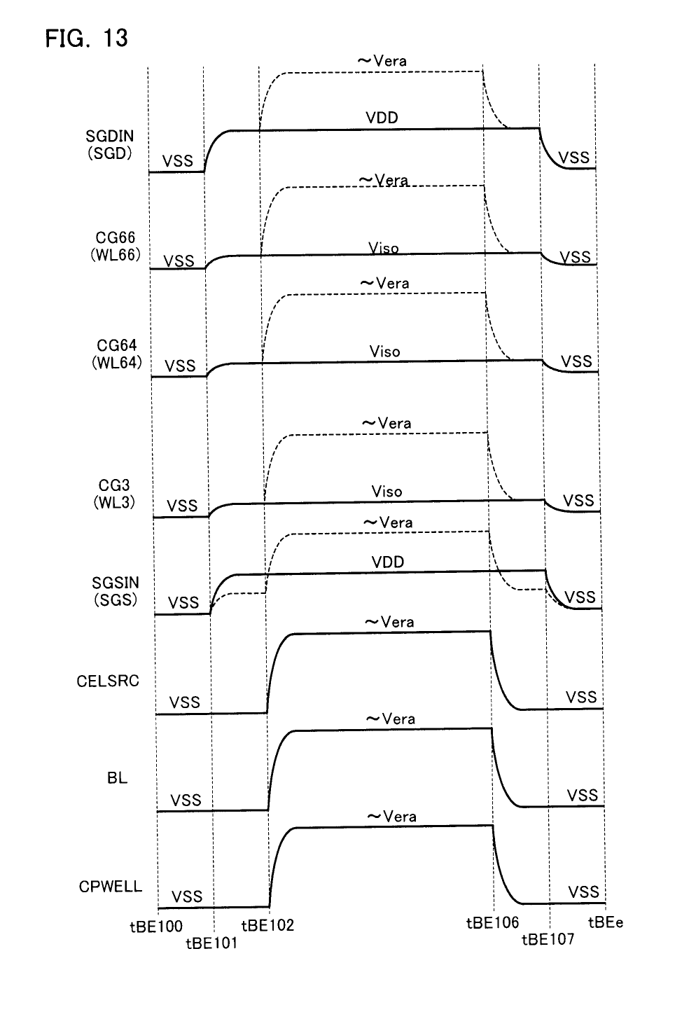

FIG. 13 illustrates the operating waveforms in the erasing step BE of Step S104. At this point, the signal lines SGSIN, SGDIN, and CG2 to CG66 are the signal lines that are connected to the selection gate lines SGS and SGD and the word lines WL2 to WL66 through the transfer transistor of the row decoder 2a to be able to detect the selection gate lines SGS and SGD and the word lines WL2 to WL66, respectively.

A cycle of times tBE100 to tBE101 is an initial state at the starting point of the erasing step BE.

Then, in a cycle of times tBE101 and tBE102, the selection gate lines SGS and SGD are charged to the power supply voltage VDD (for example, about 2.5 V), and the word lines WL2 to WL66 are initially charged to a voltage Viso (about 0.5V). At this point, after the selection gate lines SGS and SGD and the word lines WL2 to WL66 are charged to a voltage at which the threshold of the transfer transistor of the row decoder 2a drops, the transfer transistor is cut off, whereby the selection gate lines SGS and SGD and the word lines WL2 to WL66 become floating states.

Then, in a cycle of times tBE102 to tBE106, the voltage at the well CPWELL is boosted to a voltage Vera (for example, 20 V) necessary for the erasing. As a result, as illustrated by broken lines in FIG. 13, the selection gate lines SGS and SGD and the word lines WL2 to WL66 in the floating states are boosted to the vicinity of the voltage Vera by capacitive coupling. As illustrated by the broken lines of FIG. 13, the bit line BL and the common source line CELSRC are also boosted to the vicinity of the voltage Vera by a forward bias of diffusion layer coupling in the memory cell MC.

Then, in a cycle of times tBE106 to tBE107, the well CPWELL is discharged to 0 V. As a result, the bit line BL, the common source line CELSRC, the selection gate lines SGS and SGD, and the word lines WL2 to WL66 are stepped down to the vicinity of the voltage at the time tBE102.

Finally, in a cycle of times tBE107 to tBEe, the signal lines SGSIN, SGDIN, and CG2 to CG66 are discharged to, for example, the voltage VSS(0 V). As a result, the selection gate lines SGS and SGD and the word lines WL2 to WL66 are also discharged to 0 V through the transfer transistor of the row decoder 2a.

The erase step BE in Step S104 is described above. In the first embodiment, it is noted that the voltage at the well CPWELL is boosted to the voltage Vera (for example, about 15 V to about 20 V) in the cycle of the times tBE102 to tBE106.

Step S106 will be described below.

Step S106 is performed by steps of a write verify read step CV→a write step CP→the write verify read step CV→ . . . (hereinafter, the repetition of the write step CP→the write verify read step CV). The first and final steps in Step S106 may be either the write step CP or the write verify read step CV.

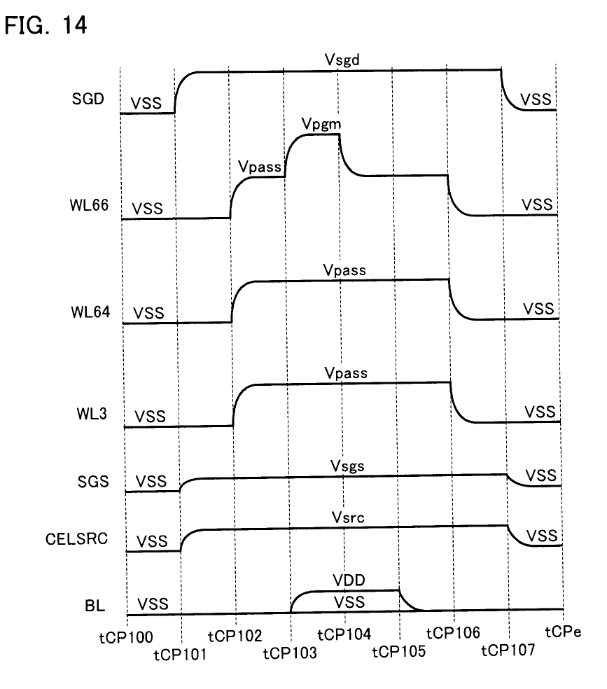

FIG. 14 illustrates the operating waveforms in the write step CP of Step S106.

A cycle of times tCP100 to tCP101 is an initial state at a starting point of the write step CP.

Then, in a cycle of times tCP101 to tCP102, the common source line CELSRC and the selection gate lines SGS and SGD are charged to voltages Vsrc (for example, 2 V), Vsgs (for example, 1.5 V), and Vsgd (for example, 2.5 V), respectively.

Then, in a cycle of times tCP102 to tCP103, the word lines WL2 to WL66 are charged to the voltage Vpass (that is of a fourth voltage, for example, 8 V).

Then, in a cycle of times tCP103 to tCP104, the specific word line WL66 is charged to a voltage Vpgm (that is of a third voltage, for example, about 20 V) necessary to write the specific data. The bit line BL through which the write is not performed is charged to the power supply voltage VDD (for example, 2.5 V), and the bit line BL through which the write is performed is charged to, for example, the voltage VSS (0 V).

Then, in a cycle of times tCP104 to tCP105, the specific word line WL66 is discharged to the voltage Vpass (for example, 8 V).

Then, in a cycle of times tCP105 to tCP106, the bit line BL is discharged to, for example, the voltage VSS (0 V).

Then, in a cycle of times tCP106 to tCP107, the word lines WL2 to WL66 are discharged to, for example, the voltage VSS (0 V).

Finally, in a cycle of times tCP107 to tCPe, the common source line CELSRC and the selection gate lines SGS and SGD are discharged to, for example, the voltage VSS (0 V).

The write step CP in Step S106 is described above. In the first embodiment, it is noted that the voltage at the specific word line WL66 is higher than the voltages at the general word lines WL2 to WL65 in the cycle of times tCP103 to tCP104.

In FIG. 14, sometimes another charge or discharge is added in the cycle of the times tCP100 to tCP101. The well CPWELL has the voltage of 0 V.

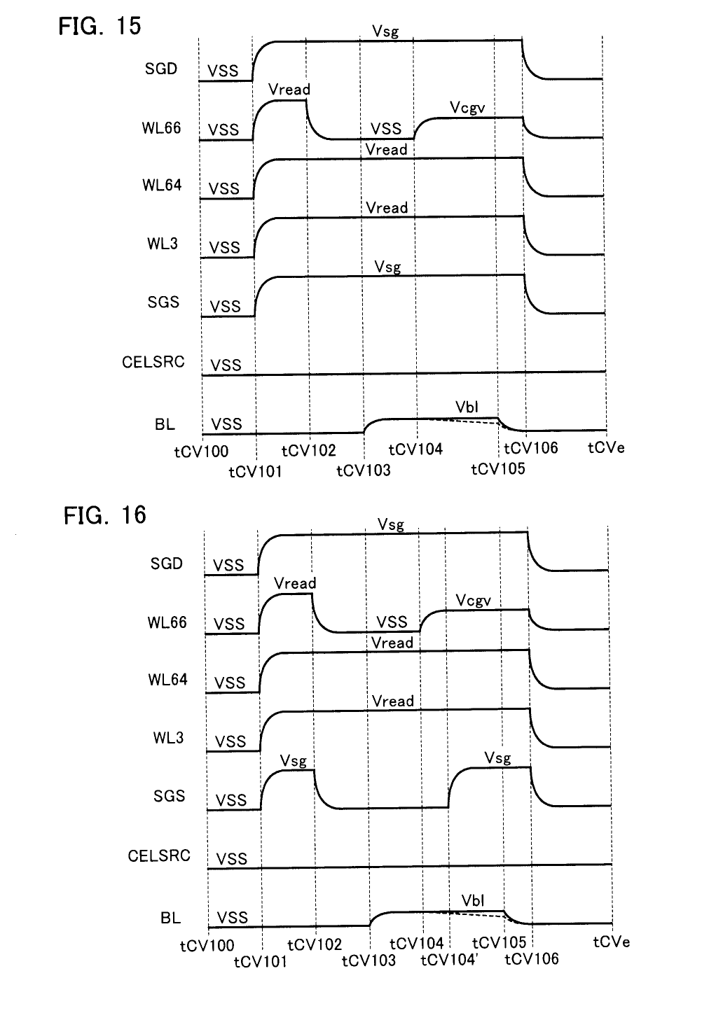

FIG. 15 illustrates the operating waveforms in the write verify read step CV of Step S106 for the use of the ABL method.

A cycle of times tCV100 to tCV101 is an initial state at a starting point of the write verify read step CV in Step S106.

Then, in a cycle of times tCV101 and tCV102, the selection gate lines SGS and SGD are boosted to the voltage Vsg (for example, 3.5 V). The word lines WL2 to WL66 are boosted to the voltage Vread (for example, 6 V). As a result, the bit line BL and the common source line CELSRC are electrically connected to initialize a channel potential at the memory cell MC. However, the cycle of the times tCV101 to tCV102 is occasionally omitted.

Then, in a cycle of times tCV102 to tCV103, the specific word line WL66 is discharged to, for example, the voltage VSS (0 V).

Then, in a cycle of times tCV103 to tCV104, the bit line BL is charged to the voltage Vb1 (for example, 0.5 V).

Then, in a cycle of times tCV104 to tCV105, a voltage Vcgv (for example, 0.5 V) necessary to read the specific data is applied to the specific word line WL66. Then the voltage at the bit line BL changes. The voltage change is detected by the sense amplifier SA of the page buffer 3, and the write operation is completed when the discharge from the bit line BL is detected.

Then, in a cycle of times tCV105 to tCV106, the bit line BL is discharged to, for example, the voltage VSS (0 V).

Finally, in a cycle of times tCV106 to tCVe, the selection gate lines SGD and SGS and the word lines WL3 to WL66 are discharged to, for example, the voltage VSS (0 V).

The write verify read step CV in Step S106 for the use of the ABL method is described above. In the first embodiment, it is noted that the voltage at the specific word line WL66 is lower than the voltages at the general word lines WL2 to WL65 in the cycle of times tCV104 to tCV105.

In FIG. 15, sometimes the common source line CELSRC is charged to the voltage higher than the voltage VSS (0 V). Sometimes the well CPWELL in which the memory cell MC is formed is charged to the voltage higher than the voltage VSS (0 V). In this case, the voltages at the bit line BL, the selection gate lines SGS and SGD, and the word lines WL2 to WL66 are substantially increased according to the voltage at the well CPWELL.

FIG. 16 illustrates the operating waveforms in the write verify read step CV of Step S106 for the use of the bit line shield method.

Because the cycle of the times tCV100 to tCV102 is identical to that of FIG. 15, the description is not repeated here.

Then, in the cycle of the times tCV102 to tCV103, the selection gate line SGS and the specific word line WL66 are discharged to, for example, the voltage VSS (0 V).

Then, in the cycle of the times tCV103 to tCV104, the bit line BL is charged to the voltage Vb1 (for example, 0.5 V).

Then, in the cycle of the times tCV104 to tCV104′, the voltage Vcgv (for example, 0.5 V) necessary to read the specific data is applied to the specific word line WL66.

Then, in the cycle of the times tCV104′ to tCV105, the selection gate line SGS is charged to the voltage Vsg (for example, 0.5V). Then the voltage at the bit line BL changes. The voltage change is detected by the sense amplifier SA of the page buffer 3, and the write operation is completed when the discharge from the bit line BL is detected.

Because the cycle of the times tCV105 to tCVe is identical to that of FIG. 33, the description is not repeated here.

The write verify read step CV in Step S106 is described above for the use of the bit line shield method. In the first embodiment, it is noted that the voltage at the specific word line WL66 is lower than the voltages at the general word lines WL2 to WL65 in the cycle of times tCV104′ to tCV105.

In FIG. 16, sometimes the common source line CELSRC is charged to the voltage higher than the voltage VSS (0 V). Sometimes the well CPWELL in which the memory cell MC is formed is charged to the voltage higher than the voltage VSS (0 V). In this case, the voltages at the bit line BL, the selection gate lines SGD and SGS, and the word lines WL2 to WL66 are substantially increased according to the voltage at the well CPWELL.

<Sequence During Write Cycle>

The operating sequence during the write cycle of the semiconductor storage device of the first embodiment will be described below.

As used herein, the write cycle means a cycle including the write operation in which the data write is performed to a specific page of the specific block and the preparation of the peripheral circuit and the post-processing for the write operation. The write cycle is typically regarded to be a cycle during which a write busy signal is active. However, the write cycle is not necessarily matched with the cycle during which the write busy signal is active.

It is assumed that the erasing operation and the write operation are included in the access operation, and it is assumed that the erasing cycle and the write cycle are included in the access cycle.

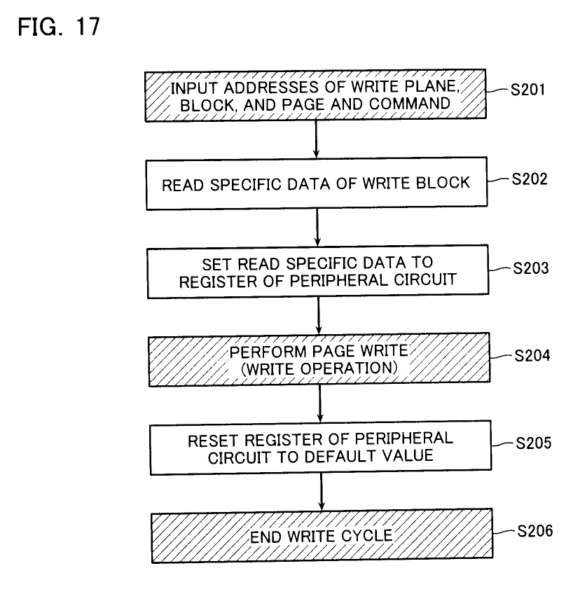

FIG. 17 is a view illustrating the operating sequence during the write cycle. Steps S201, S204, and S206 indicated by the hatched lines in FIG. 17 correspond to the operating sequence during the write cycle of the related art. However, the operations in Steps S201, S204, and S206 are not necessarily matched with those of the related art.

First, in Step S201, the addresses to be written of the plane, the block, and the page and the command are input from the outside through the controller 11. The addresses of the plane, the block, and the page are transmitted to the row address register 5a and the column address register 5b through the I/O buffer 9. The command is transmitted to the sequence control circuit 7 through the logic control circuit 6.

In Step S202, the specific data stored in the block (hereinafter referred to as a “write block”) that becomes the write target is read on the page buffer 3.

In Step S203, the specific data retained in the page buffer 3 is set to the register of the peripheral circuit such as the sequence control circuit 7.

In Step S204, the circuit operating parameter is adjusted using the specific data set to the register of the peripheral circuit, and the peripheral circuit is operated according to the adjusted circuit operating parameter to write the data in the page of the write block (write operation).

Finally, in Step S205, the specific data retained in the register of the peripheral circuit is reset to a predetermined default value. Then the write cycle is ended (Step S206).

As described above, in the first embodiment, the circuit operating parameter is adjusted using the specific data prepared in each block, so that the optimum write operation can be implemented in each block.

### Summary of First Embodiment

As described above, according to the first embodiment, the semiconductor storage device in which the degradation of the reliability or performance is suppressed even if the microfabrication advances can be provided because the erasing operation or the write operation is performed in each block using the specific data independently of the operating circuit parameter. Because the specific data is stored in the memory cell, the capacity of the specific data that can be stored can easily be increased, and a risk of erasing the specific data due to the accidental cutoff of the power supply can be reduced in the case of the nonvolatile memory cell.

### Second Embodiment

Specific data writing and reading methods of a semiconductor storage device according to a second embodiment will be described below.

The specific data is used to properly perform the operation of the peripheral circuit during the data write operation and the data erasing operation in the block, and therefore the extremely high reliability is required for the specific data.

Accordingly, desirably the specific data is stored in 1 bit/cell in order to suppress the threshold variation of the specific memory cell due to the intercell interference.

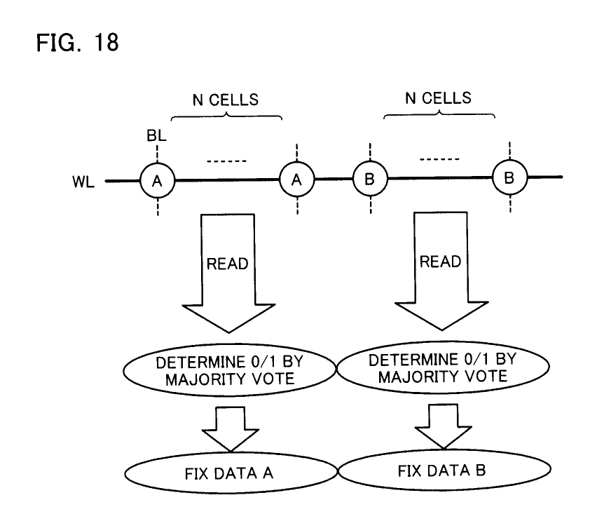

In the second embodiment, as illustrated in FIG. 18, the specific data is dealt with in order to further improve the reliability.

In FIG. 18, pieces of 1-bit specific data A, B, . . . are written in each of N (for example, 8 (1 byte)) specific memory cells. After the specific data is read from the N specific memory cells, the column decoder 2b makes a determination by majority vote to fix the pieces of specific data A, B, . . . .

As described above, according to the second embodiment, not only the same effect as the first embodiment is obtained, but also the normal specific data can be read even if the threshold of part of the specific memory cells varies due to the intercell interference because the specific data is stored in the plural specific memory cells.

### Third Embodiment

A semiconductor storage device according to a third embodiment suppresses the threshold variation of the specific memory cell due to the intercell interference.

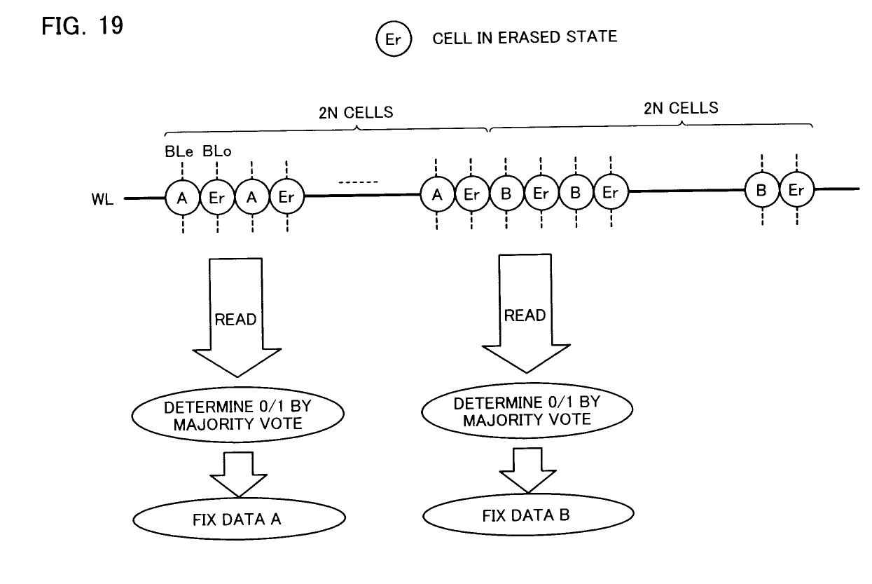

In the third embodiment, as illustrated in FIG. 19, the memory cell, which is selected by one (in FIG. 19, the bit line BLe) of the even-numbered bit line BLe and the even-numbered bit line BLo connected to the specific word line WL, is used as the specific memory cell, and the memory cell selected by the other bit line (in FIG. 19, the bit line BLo) is used as the dummy cell in the erased state (Er).

In the case that the pieces of 1-bit specific data A, B, . . . are written in each of the N (for example, 8 (1 byte)) specific memory cells similarly to the second embodiment, the 2N memory cells of the specific memory cells and the dummy cells are required in total in order to store the pieces of 1-bit specific data.

Because the read of the specific data is identical to that of the second embodiment, the description is not repeated here.

As described above, according to the third embodiment, the same effect as the first and second embodiments is obtained. Additionally, because the dummy cell is disposed between the specific memory cells, the influence of the intercell interference is decreased compared with the second embodiment, and the high-reliability specific data can be stored.

### Fourth Embodiment

Similarly to the third embodiment, a semiconductor storage device according to a fourth embodiment suppresses the threshold variation of the specific memory cell due to the intercell interference. The fourth embodiment can be applied to the case that the plural specific word lines are disposed adjacent to each other like the cases 24 and 34 illustrated in FIG. 4.

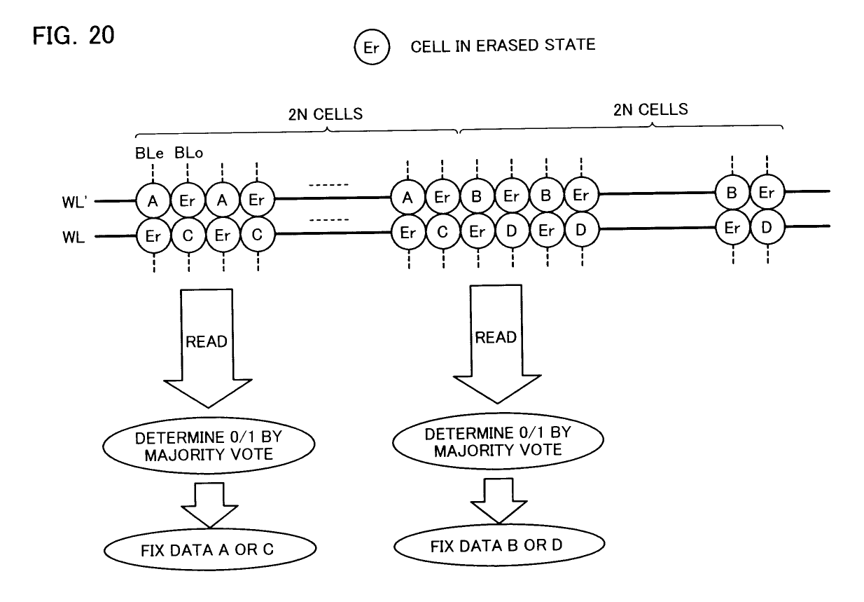

In the fourth embodiment, the specific memory cells and the dummy cells are alternately disposed in the word line direction while the specific memory cells are disposed so as not to be adjacent to each other in the bit line direction. In FIG. 20, the two specific word lines WL and WL′ are disposed. In the specific word line WL, the memory cell selected by the even-numbered bit line BLe is used as the specific memory cell, and the memory cell selected by the odd-numbered bit line BLo is used as the dummy cell in the erased state (Er). On the other hand, in the specific word line WL', the memory cell selected by the odd-numbered bit line BLo is used as the specific memory cell, and the memory cell selected by the odd-numbered bit line BLe is used as the dummy cell in the erased state (Er).

Because the read of the specific data is identical to that of the second and third embodiments, the description is not repeated here.

In the case that the pieces of specific data A, B, . . . are written in each of the N (for example, 8 (1 byte)) specific memory cells, the 2N memory cells of the specific memory cells and the dummy cells are required in total in order to store the pieces of 1-bit specific data similarly to the third embodiment.

As described above, according to the fourth embodiment, the same effect as the first and second embodiments is obtained. Additionally, the number of pieces of specific data dealt with can be increased compared with the third embodiment while the increase of the influence of the intercell interference is suppressed between the specific memory cells adjacent to each other in the word line direction and the bit line direction.

[Spacer Patterning Process]

The above-described spacer patterning process that can be used to produce the semiconductor devices of the above embodiments will supplementarily be described below.

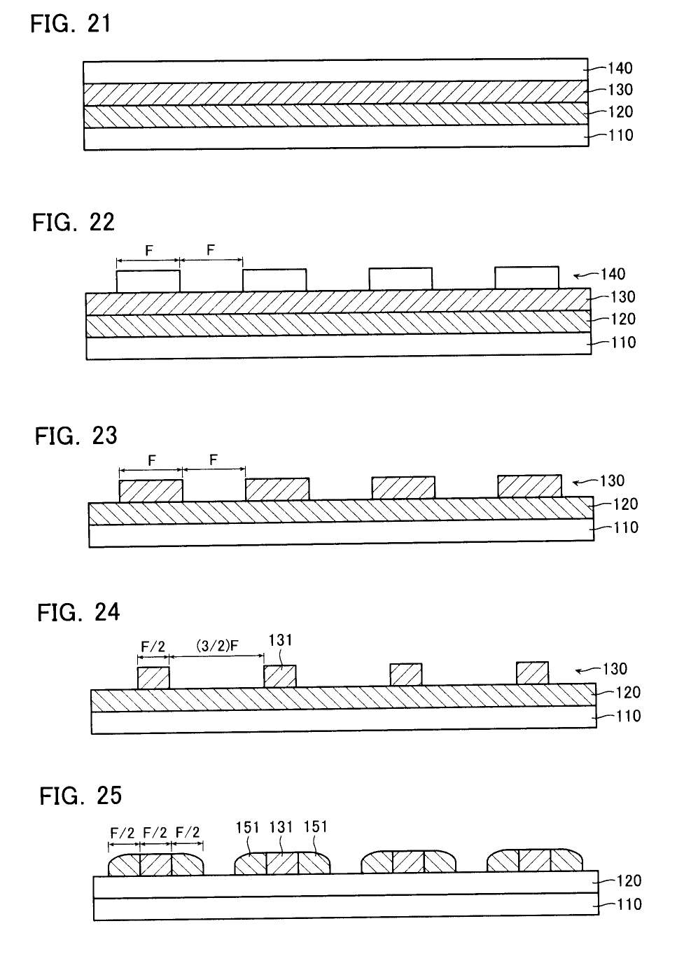

The spacer patterning process of forming the L/S pattern having a line width of F/2 and a space width of F/2 will be described with reference to FIGS. 21 to 27. At this point, the sign F designates the minimum processing size of the resolution of the lithography technology.

First, as illustrated in FIG. 21, after a processed film 110 including the memory cell and the interconnection is formed, a first mask 120 and a second mask 130, which are made of SiO₂, are sequentially stacked on the processed film 110. A photoresist 140 is applied on an upper surface of the second mask 130 by spin coating.

Then, as illustrated in FIG. 22, the L/S pattern having the line width of F and the space width of F is exposed to the photoresist 140.

Then, as illustrated in FIG. 23, the L/S pattern of the photoresist 140 is transferred to the second mask 130 using the lithography technology. Therefore, the L/S pattern having the line width of F and the space width of F is formed on the second mask 130.

Then, as illustrated in FIG. 24, both side surfaces of line of the second mask 130 are removed by F/4 using a slimming technology in which RIE (Reactive Ion Etching) is used. Therefore, the L/S pattern having the line width of F/2 and the space width of (3/2) F is formed on the second mask 130.

Then, as illustrated in FIG. 25, the line of the second mask 130 is used as a core material 131, and a SiO₂ sidewall 151 having the width of F/2 is formed on each of the side surfaces.

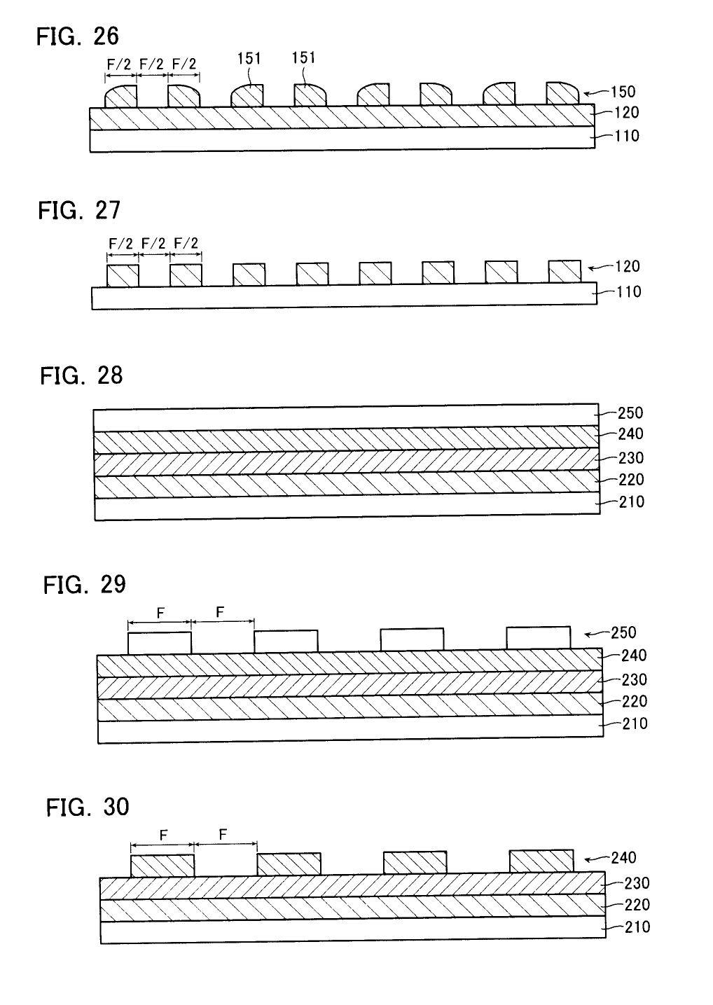

Then, as illustrated in FIG. 26, the core material 131 is removed by wet etching using, for example, DHF (Dilute Hydrofluoric Acid). Therefore, an L/S pattern 150 having the line width of F/2 and the space width of F/2 is formed.

Then, as illustrated in FIG. 27, the L/S pattern having the line width of F/2 and the space width of F/2 is formed in the first mask 120 using anisotropic etching such as the RIE.

Then, the etching is performed using the L/S pattern of the second mask 120, which allows the processed film 110 to be processed in the minimum processing size of F/2.

The spacer patterning process of forming the L/S pattern having a line width of F/4 and a space width of F/4 will be described with reference to FIGS. 28 to 38.

First, as illustrated in FIG. 28, after a processed film 210 including the memory cell and the interconnection is formed, a first mask 220, a second mask 230, and a third mask 240, which are made of SiO₂, are sequentially stacked on the processed film 210. A photoresist 250 is applied on the upper surface of the third mask 240 by the spin coating.

Then, as illustrated in FIG. 29, the L/S pattern having the line width of F and the space width of F is exposed to the photoresist 250.

Then, as illustrated in FIG. 30, the L/S pattern of the photoresist 250 is transferred to the third mask 240 using the lithography technology. Therefore, the L/S pattern having the line width of F and the space width of F is formed on the third mask 240.

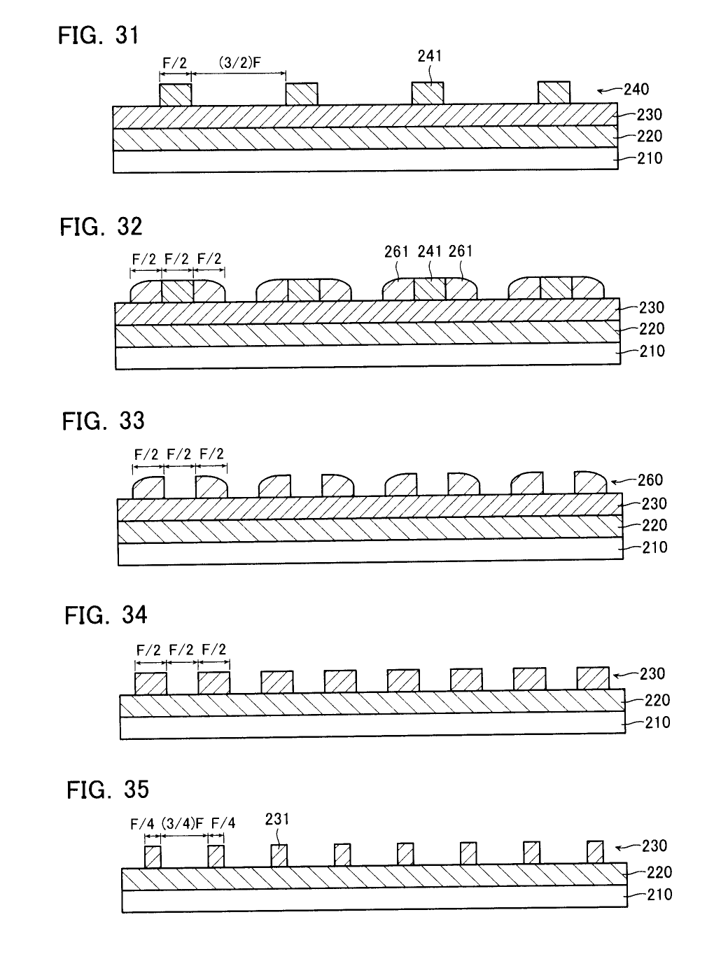

Then, as illustrated in FIG. 31, both the side surfaces of line of the third mask 240 are removed by F/4 using the slimming technology in which the RIE is used. Therefore, the L/S pattern having the line width of F/2 and the space width of (3/2) F is formed on the third mask 240.

Then, as illustrated in FIG. 32, the line of the third mask 240 is used as a core material 241, and a SiO₂ sidewall 261 having the width of F/2 is formed on each of the side surfaces.

Then, as illustrated in FIG. 33, the core material 241 is removed by the wet etching using, for example, the DHF. Therefore, an L/S pattern 260 having the line width of F/2 and the space width of F/2 is formed.

Then, as illustrated in FIG. 34, the L/S pattern having the line width of F/2 and the space width of F/2 is formed in the second mask 230 using the anisotropic etching such as the RIE.

Then, as illustrated in FIG. 35, both the side surfaces of line of the second mask 230 are removed by F/8 using the slimming technology in which the RIE is used. Therefore, the L/S pattern having the line width of F/4 and the space width of (3/4) F is formed on the second mask 230.

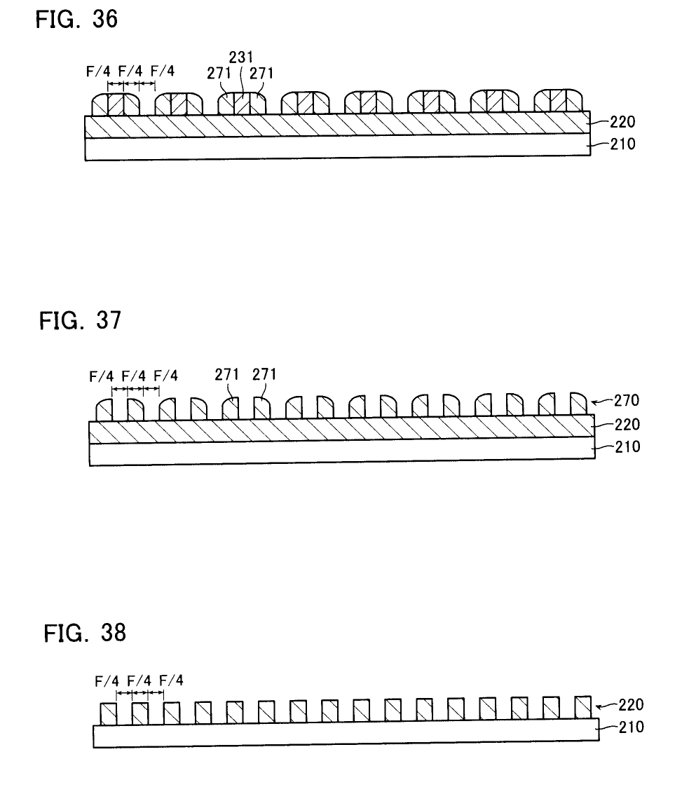

Then, as illustrated in FIG. 36, the line of the second mask 230 is used as a core material 231, and a SiO₂ sidewall 271 having the width of F/4 is formed on each of the side surfaces.

Then, as illustrated in FIG. 37, the core material 231 is removed by the wet etching using, for example, the DHF. Therefore, an L/S pattern 270 having the line width of F/4 and the space width of F/4 is formed.

Then, as illustrated in FIG. 38, the L/S pattern having the line width of F/4 and the space width of F/4 is formed in the first mask 220 using the anisotropic etching such as the RIE.

Then, the etching is performed using the L/S pattern of the first mask 220, which allows the processed film 210 to be processed in the minimum processing size of F/4.

As described above with reference to FIGS. 21 to 27 and FIGS. 28 to 38, the microfabrication can be implemented by the minimum processing size of 1/2 every time the spacer patterning process is performed.

### OTHER

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a memory cell array including a plurality of word lines, a plurality of bit lines, and a plurality of memory cells each of which is selected by the word line and the bit line, the memory cell array being divided into a plurality of blocks, some of the word lines being set to a specific word line, at least some of or all the memory cells in each block being set to specific memory cells, the memory cell being accessed by the specific word line, the specific data except user data being stored in the specific memory cell; and
an erasing circuit that erases the memory cell of the memory cell array, the erasing circuit referring to the specific data stored in the specific memory cell belonging to the certain block in performing an erasing operation to the memory cell belonging to the certain block.

2. The semiconductor storage device according to claim 1, wherein the specific data is written in the specific memory cell belonging to the certain block after the erasing operation during an erasing cycle including the erasing operation of the memory cell belonging to the certain block.

3. The semiconductor storage device according to claim 1, wherein the specific data is read from the specific memory cell before the erasing operation during an erasing cycle including the erasing operation of the memory cell.

4. The semiconductor storage device according to claim 1, wherein the memory cell array includes a dummy word line that is not used to store the user data in addition to the word line that selects the memory cell in which the user data is stored.

5. The semiconductor storage device according to claim 4, wherein the specific word line doubles as the dummy word line.

6. The semiconductor storage device according to claim 1, wherein only the specific data is stored in some of the specific memory cell,
the memory cell adjacent to the specific memory cell selected by the specific word line in the plurality of memory cells selected by the certain specific word line is a dummy cell that is not used to store data,
the memory cell array includes the two specific word lines adjacent to each other, the specific memory cell selected by one of the two specific word lines and the specific memory cell selected by the other specific word line are not adjacent to each other,
the identical specific data is written in the plurality of specific memory cells in the memory cell array, and
the erasing circuit determines data, which is stored in the plurality of specific memory cells in each of which the identical specific data is written, by majority vote when referring to the specific data.

7. The semiconductor storage device according to claim 5, wherein the memory cell array includes the plurality of dummy word lines, and
some of the plurality of dummy word lines double as the specific word lines.

8. A semiconductor storage device comprising:
a memory cell array including a plurality of word lines, a plurality of bit lines, and a plurality of memory cells each of which is selected by the word line and the bit line, the memory cell array being divided into a plurality of blocks, some of the word lines being set to a specific word line, at least some of or all the memory cells in each block being set to specific memory cells, the memory cell being accessed by the specific word line, the specific data except user data being stored in the specific memory cell; and
an erasing circuit that erases the memory cell of the memory cell array, the erasing circuit having a cycle during which a first voltage is applied to the specific word line belonging to the certain block while a second voltage different from the first voltage is applied to the remaining word lines before an erasing operation during an erasing cycle of the memory cell belonging to the certain block, the erasing cycle including the erasing operation performed to the memory cell and processing necessary for the erasing operation.

9. The semiconductor storage device according to claim 8, wherein the erasing circuit has a cycle during which a third voltage is applied to the specific word line belonging to the certain block while a fourth voltage different from the third voltage is applied to the remaining word lines after the erasing operation during the erasing cycle of the memory cell belonging to the certain block.

10. The semiconductor storage device according to claim 8, wherein the memory cell array includes a dummy word line that is not used to store the user data in addition to the word line that selects the memory cell in which the user data is stored.

11. The semiconductor storage device according to claim 10, wherein the specific word line doubles as the dummy word line.

12. The semiconductor storage device according to claim 8, wherein only the specific data is stored in some of the specific memory cell,
the memory cell adjacent to the specific memory cell selected by the specific word line in the plurality of memory cells selected by the certain specific word line is a dummy cell that is not used to store data,
the memory cell array includes the two specific word lines adjacent to each other, the specific memory cell selected by one of the two specific word lines and the specific memory cell selected by the other specific word line are not adjacent to each other,
the identical specific data is written in the plurality of specific memory cells in the memory cell array, and the erasing circuit determines data stored in the plurality of specific memory cells in each of which the identical specific data is written by majority vote.

13. The semiconductor storage device according to claim 11, wherein the memory cell array includes the plurality of dummy word lines, and
some of the plurality of dummy word lines double as the specific word lines.

14. A semiconductor storage device comprising:
a memory cell array including a plurality of word lines, a plurality of bit lines, and a plurality of memory cells each of which is selected by the word line and the bit line, the memory cell array being divided into a plurality of blocks, some of the word lines being set to a specific word line, at least some of or all the memory cells in each block being set to specific memory cells, the memory cell being accessed by the specific word line, the specific data except user data being stored in the specific memory cell; and
an access circuit that accesses the memory cell of the memory cell array, the access circuit referring to the specific data stored in the specific memory cell belonging to the certain block in performing an access operation to the memory cell belonging to the certain block.

15. The semiconductor storage device according to claim 14, wherein the specific data is written in the specific memory cell belonging to the certain block after an erasing operation during an erasing cycle including the erasing operation of the memory cell belonging to the certain block.

16. The semiconductor storage device according to claim 14, wherein the specific data is read from the specific memory cell before the access operation during the access cycle including the access operation of the memory cell.

17. The semiconductor storage device according to claim 14, wherein the memory cell array includes a dummy word line that is not used to store the user data in addition to the word line that selects the memory cell in which the user data is stored.

18. The semiconductor storage device according to claim 17, wherein the specific word line doubles as the dummy word line.

19. The semiconductor storage device according to claim 14, wherein only the specific data is stored in some of the specific memory cell,
the memory cell adjacent to the specific memory cell selected by the specific word line in the plurality of memory cells selected by the certain specific word line is a dummy cell that is not used to store data,
the memory cell array includes the two specific word lines adjacent to each other, the specific memory cell selected by one of the two specific word lines and the specific memory cell selected by the other specific word line are not adjacent to each other,
the identical specific data is written in the plurality of specific memory cells in the memory cell array, and
the access circuit determines data, which is stored in the plurality of specific memory cells in each of which the identical specific data is written, by majority vote when referring to the specific data.

20. The semiconductor storage device according to claim 18, wherein the memory cell array includes the plurality of dummy word lines, and
some of the plurality of dummy word lines double as the specific word lines.
